(19) United States
(12) Patent Application Publication
(10) Pub. No.: US 2024/0032369 A1
(43) Pub. Date: Jan. 25, 2024

(54) DUAL-SIDED DISPLAY PANEL AND METHOD OF MANUFACTURING SAME

(71) Applicant: Jie PAN, Wuhan, Hubei (CN)

(72) Inventor: Jie PAN, Wuhan, Hubei (CN)

(73) Assignees: Wuhan China Star Optoelectronics Technology Co., Ltd., Wuhan, Hubei (CN); Wuhan China Star Optoelectronics Semiconductor Display Technology Co., Ltd., Wuhan, Hubei (CN)

(21) Appl. No.: 17/414,350

(22) PCT Filed: May 21, 2021
(86) PCT No.: PCT/CN2021/095195

§ 371 Date: Nov. 7, 2022

(30) Foreign Application Priority Data
May 12, 2021 (CN) 202110515773.3

(51) Int. Cl. H10K 59/35; H10K 59/12; H10K 59/176; H10K 59/128

(52) U.S. Cl. CPC H10K 59/35; H10K 59/1201; H10K 59/176; H10K 59/128; H10K 59/173

(57) ABSTRACT

A dual-sided display panel and a method of manufacturing the same are disclosed. By setting part of a red pixel light-emitting layer and part of a green pixel light-emitting layer to correspond to first pixel definition layers, and setting another part of the red pixel light-emitting layer and another part of the green pixel light-emitting layer to correspond to blue pixel light-emitting layers, only a first portion and a third portion can emit light, so that on the basis of not reducing lengths of the red pixel light-emitting layer and the green pixel light-emitting layer, an irradiation range of light emitted by each of the red pixel light-emitting layer and the green pixel light-emitting layer is reduced.

### BACKGROUND OF INVENTION

### 1. Field of Invention

The present application relates to a technical field of displays, and more particularly to a dual-sided display panel and a method of manufacturing same.

### 2. Related Art

Currently, with development of organic light-emitting diode (OLED) technologies, OLED display screens, due to their advantages of flexibility and portability, have been applied to more and more consumer electronics fields, such as mobile phones, tablets, in-vehicle control devices, electronic tags, smart speakers, and other technological products. OLED display screens are continuing to expand on application ranges, and their potential is constantly being exploited.

As consumers' pursuit of display quality keeps getting higher, demands for high-resolution mobile phones have been growing to a significant extent. Resolution of current OLED displays mainly depends on size of pixel openings. To manufacture high-resolution panels, the pixel openings need to be as small as possible. However, if pixel opening size continues to become smaller, it will give rise to problems, such as difficulty in production process, color mixing, etc.

Therefore, how to improve resolution of display panels to meet consumers' needs of the resolution of the display panels becomes a difficult problem that current display panel manufacturers have to endeavor to overcome.

### SUMMARY OF INVENTION

An object of the present application is to provide a dual-sided display panel and a method of manufacturing the same to overcome a technical problem that resolution of current display panels cannot meet the needs of consumers.

An embodiment of the present application provides a dual-sided display panel, comprising a first organic light-emitting unit and a second organic light-emitting unit disposed in a stacked arrangement; wherein the first organic light-emitting unit comprises a plurality of first pixel definition layers and a plurality of blue pixel light-emitting layers, a first gap is defined between adjacent ones of the first pixel definition layers, and the blue pixel light-emitting layers are filled in the first gaps; wherein the second organic light-emitting unit comprises a plurality of second pixel definition layers, a plurality of red pixel light-emitting layers, and a plurality of green pixel light-emitting layers, a second gap is defined between adjacent ones of the second pixel definition layers, and the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers comprises a first portion and a second portion adjoining each other, each of the green pixel light-emitting layers comprises a third portion and a fourth portion adjoining each other, the first portion and the third portion are disposed corresponding to the first pixel definition layers, and the second portion and the fourth portion are disposed corresponding to the blue pixel light-emitting layers.

Optionally, the first organic light-emitting unit further comprises a first anode layer and a first cathode layer, the first anode layer is disposed on a side of the blue pixel light-emitting layer away from the second organic light-emitting unit, and the first cathode layer is disposed on a side of the blue pixel light-emitting layer adjacent to the second organic light-emitting unit.

Optionally, the second organic light-emitting unit further comprises a second anode layer and a second cathode layer, the second anode layer is disposed on a side of the red pixel light-emitting layer away from the first organic light-emitting unit, the second cathode layer is disposed on a side of the red pixel light-emitting layer adjacent to the first organic light-emitting unit, and a side of the second cathode layer adjacent to the first organic light-emitting unit overlaps a side of the first cathode layer adjacent to the second organic light-emitting unit.

Optionally, the second anode layer comprises a reflective anode layer and a transparent anode layer adjoining each other, each of the first portion and the third portion is disposed corresponding to the reflective anode layer, and each of the second portion and the fourth portion is disposed corresponding to the transparent anode layer.

Optionally, the dual-sided display panel further comprises a conversion layer disposed on a side of the transparent anode layer away from the first organic light-emitting unit and provided corresponding to the transparent anode layer.

Optionally, the dual-sided display panel further comprises an adhesion layer disposed between the first encapsulation layer and the second encapsulation layer.

Optionally, each of the first pixel definition layer and the second pixel definition layer is made of colorless polyimide.

Optionally, the reflective anode layer has a length less than or equal to a length of the transparent anode layer.

Optionally, each of the blue pixel light-emitting layer, the red pixel light-emitting layer, and the green pixel light-emitting layer has a length between 20 microns (μm) and 25 μm.

An embodiment of the present application provides a method of manufacturing a dual-sided display panel, comprising forming a first organic light-emitting unit, and the first organic light-emitting unit comprising a first surface and a second surface disposed opposite to each other, a plurality of first pixel definition layers, a plurality of blue pixel light-emitting layers, and a first gap defined between adjacent ones of the first pixel definition layers, wherein the blue pixel light-emitting layers are filled in the first gaps; forming a second organic light-emitting unit, and the second organic light-emitting unit comprising a plurality of second pixel definition layers, a plurality of red pixel light-emitting layers, a plurality of green pixel light-emitting layers, and a second gap defined between adjacent ones of the second pixel definition layers, wherein the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers comprises a first portion and a second portion adjoining each other, and each of the green pixel light-emitting layers comprises a third portion and a fourth portion adjoining each other; and attaching the first organic light-emitting unit to the second organic light-emitting unit such that the first organic light-emitting unit and the second organic light-emitting unit are staggered, so that the first organic light-emitting unit and the second organic light-emitting unit are disposed in a stacked arrangement, the first portion and the third portion are disposed corresponding to the first pixel definition layers, and the second portion and the fourth portion are disposed corresponding to the blue pixel light-emitting layers.

The present application has advantageous effects as follows: in the dual-sided display panel and the method of manufacturing the same provided by the embodiments of the present application, the first organic light-emitting unit includes the blue pixel light-emitting layers and the first pixel definition layers, and the second organic light-emitting unit includes the second pixel definition layers, the red pixel light-emitting layers, and the green pixel light-emitting layers. Each of the red pixel light-emitting layers includes the first portion and the second portion adjoining each other, and each of the green pixel light-emitting layers includes the third portion and the fourth portion adjoining each other. The first portion and the third portion are disposed to correspond to the first pixel definition layers, and the second portion and the fourth portion are disposed to correspond to the blue pixel light-emitting layers. Since the first pixel definition layers are transparent, only light emitted by the first portion and the third portion can be output from the first pixel definition layers, so that on the basis of not reducing lengths of the red pixel light-emitting layer and the green pixel light-emitting layer, an irradiation range of the light emitted by each of the red pixel light-emitting layer and the green pixel light-emitting layer is reduced, thereby increasing the resolution of the dual-sided display panel and satisfying the needs of consumers.

### BRIEF DESCRIPTION OF DRAWINGS

In order to more clearly illustrate the technical solutions in the embodiments of the present application, the following briefly introduces the accompanying drawings for describing the embodiments. Apparently, the accompanying drawings in the following description show merely some embodiments of the present application, and a person skilled in the art may still derive other drawings from these accompanying drawings without creative efforts.

FIG. 1 is a first schematic structural view of a dual-sided display panel provided by an embodiment of the present application.

FIG. 2 is a second schematic structural view of a dual-sided display panel provided by an embodiment of the present application.

FIG. 3 is a third schematic structural view of a dual-sided display panel provided by an embodiment of the present application.

FIG. 4 is a fourth schematic structural view of a dual-sided display panel provided by an embodiment of the present application.

FIG. 5 is a fifth schematic structural view of a dual-sided display panel provided by an embodiment of the present application.

FIG. 6 is a sixth schematic structural view of a dual-sided display panel provided by an embodiment of the present application.

FIG. 7 is a seventh schematic structural view of a dual-sided display panel provided by an embodiment of the present application.

FIG. 8 is a flowchart of a method of manufacturing a dual-sided display panel provided by an embodiment of the present application.

### DESCRIPTION OF PREFERRED EMBODIMENTS

The technical solutions in the embodiments of the present application will be clearly and completely described in the following with reference to the accompanying drawings in the embodiments. Apparently, the embodiments as described are only a part, but not all, of the embodiments of the present application. Based on the embodiments in the present application, all other embodiments obtained by those skilled in the art without creative efforts shall be within the scope of the present application.

In the description of this application, it needs to be understood that the orientation or positional relationship indicated by the terms “length”, “width”, “thickness”, “upper”, “lower”, etc. are based on the orientation or positional relationship shown in the drawings, just to facilitate the description of this application and simplify the description, but does not indicate or imply that the device or element referred to must have a particular orientation in a particular orientation construction and operation, and therefore not be construed as limitations of the present application. In the description of the present application, the meaning of “a plurality” is two or more unless specifically and specifically defined otherwise.

In the present application, unless otherwise expressly specified or limited, the first feature being “on” or “lower” the second feature may include direct contact of the first and the second features and may also include that the first and the second features are not in direct contact, but in contact by the additional features therebetween.

An embodiment of the present application provides a dual-sided display panel and a method of manufacturing same. Detailed descriptions are given below. It should be noted that the order of description in the following embodiments is not meant to limit the preferred order of the embodiments.

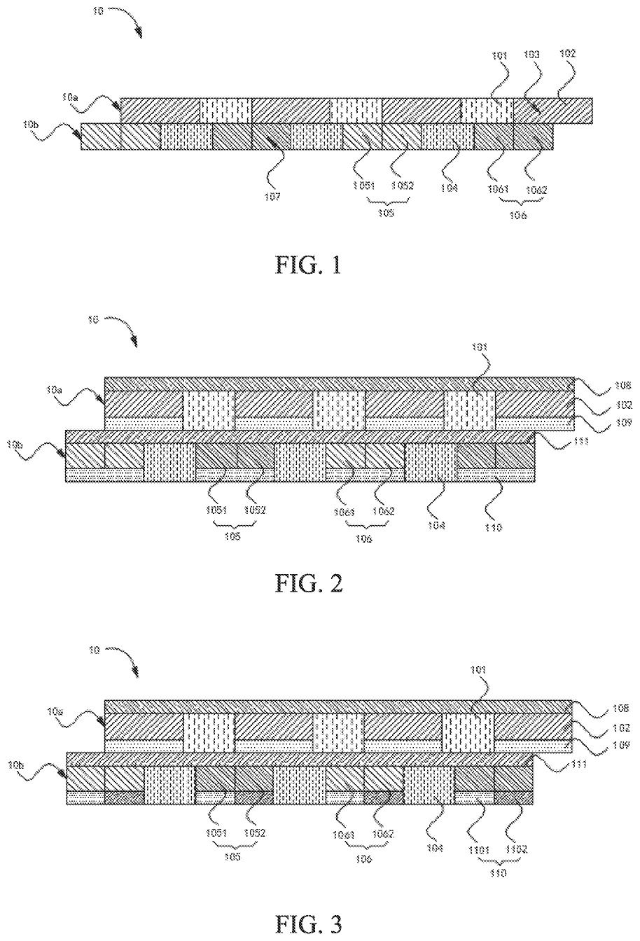

Specifically, please refer to FIG. 1, which is a first schematic structural view of a dual-sided display panel provided by an embodiment of the present application. A dual-sided display panel 10 provided by an embodiment of the present application includes a first organic light-emitting unit 10a and a second organic light-emitting unit 10b disposed in a stacked arrangement, wherein the first organic light-emitting unit 10a includes a plurality of first pixel definition layers 101 and a plurality of blue pixel light-emitting layers 102. A first gap 103 is defined between adjacent ones of the first pixel definition layers 101, and the blue pixel light-emitting layers 102 are filled in the first gaps 103. The second organic light-emitting unit 10b includes a plurality of second pixel definition layers 104, a plurality of red pixel light-emitting layers 105, and a plurality of green pixel light-emitting layers 106. A second gap 107 is defined between adjacent ones of the second pixel definition layers 104, and the red pixel light-emitting layers 105 and the green pixel light-emitting layers 106 are filled in the second gaps 107. The red pixel light-emitting layers 105 and the green pixel light-emitting layers 106 are sequentially disposed and spaced apart from each other in a direction from the blue pixel light-emitting layer 102 to the first pixel definition layer 101.

Each of the red pixel light-emitting layers 105 includes a first portion 1051 and a second portion 1052 adjoining each other, each of the green pixel light-emitting layers 106 includes a third portion 1061 and a fourth portion 1062 adjoining each other. The first portion 1051 and the third portion 1061 are disposed corresponding to the first pixel definition layers 101, and the second portion 1052 and the fourth portion 0162 are disposed corresponding to the blue pixel light-emitting layers 102.

Specifically, it should be noted that resolution is precision of screen images and refers to number of pixels that a display panel can display per unit area. Therefore, the higher the resolution is, the higher the density of an image displayed a display screen is, so that the display panel can present images with finer details and higher fidelity.

Specifically, it should be noted that the first pixel definition layers 101 are generally made of a transparent material. Therefore, both the first portion 1051 and the third portion 1061 can emit light through the first pixel definition layers 101, so that number of pixels that the dual-sided display panel 10 can display per unit area increases without changing an area of the blue pixel light-emitting layer 102, thereby increasing resolution of the dual-sided display panel 10, improving display effects of the dual-sided display panel 10, and satisfying needs of consumers.

Specifically, in one embodiment, each of the first pixel definition layer 101 and the second pixel definition layer 104 is made of colorless polyimide.

Specifically, in one embodiment, a thickness of the blue pixel light-emitting layer 102 is between 250 angstroms (Å) and 1000 Å. More specifically, the thickness of the blue pixel light-emitting layer 102 is 250 Å, 300 Å, 350 Å, 450 Å, 550 Å, 700 Å, 850 Å, or 1000 Å, wherein the specific thickness of the blue pixel light-emitting layer 102 is set by specific process requirements of the dual-sided display panel 10.

Specifically, in one embodiment, a thickness of the red pixel light-emitting layer 105 is between 500 Å and 2000 Å. More specifically, the thickness of the red pixel light-emitting layer 105 is 500 Å, 600 Å, 700 Å, 900 Å, 1100 Å, 1400 Å, 1700 Å, or 2000 Å, wherein the specific thickness of the red pixel light-emitting layer 105 is set by specific process requirements of the dual-sided display panel 10.

Specifically, in one embodiment, a thickness of the green pixel light-emitting layer 106 is between 400 Å and 1000 Å. More specifically, the thickness of the green pixel light-emitting layer 106 is 400 Å, 450 Å, 500 Å, 600 Å, 700 Å, 800 Å, 900 Å, or 1000 Å, wherein the specific thickness of the red pixel light-emitting layer 106 is set by specific process requirements of the dual-sided display panel 10.

Specifically, in one embodiment, each of the blue pixel light-emitting layer 102, the red pixel light-emitting layer 105, and the green pixel light-emitting layer 106 has a length between 20 microns (μm) and 25 μm.

It should be noted that the shorter the length of each of the blue pixel light-emitting layer 102, the red pixel light-emitting layer 105, and the green pixel light-emitting layer 106 is, the greater the number of the pixels that the display panel 10 can display per unit area is, and the higher the resolution of the dual-sided display panel 10 is. Therefore, when the lengths of the blue pixel light-emitting layer 102, the red pixel light-emitting layer 105, and the green pixel light-emitting layer 106 are all 20 microns, the dual-sided display panel 10 has a highest resolution.

Please refer to FIG. 2, which is a second schematic structural view of a dual-sided display panel 10 provided by an embodiment of the present application. The dual-sided display panel 10 shown in FIG. 2 differs from the dual-sided display panel 10 shown in FIG. 1 in that the first organic light-emitting unit 10a further includes a first anode layer 108 and a first cathode layer 109. The first anode layer 108 is disposed on a side of the blue pixel light-emitting layer 102 away from the second organic light-emitting unit 10b, and the first cathode 109 is disposed on a side of the blue pixel light-emitting layer 102 adjacent to the second organic light-emitting unit 10b. The second organic light-emitting unit 10b further includes a second anode layer 110 and a second cathode layer 111. The second anode layer 110 is disposed on a side of the red pixel light-emitting layer 105 away from the first organic light-emitting unit 10a. The second cathode layer 111 is disposed on a side of the red pixel light-emitting layer 105 adjacent to the first organic light-emitting unit 10a. A side of the second cathode layer 111 adjacent to the first organic light-emitting unit 10a overlaps a side of the first cathode layer 109 adjacent to the second organic light-emitting unit 10b.

Specifically, it should be noted that the first anode layer 108 is made of a transparent material. Specifically, the first anode layer 108 is made of indium tin oxide or indium zinc oxide. Therefore, the blue pixel light-emitting layer 102, the red pixel light-emitting layer 105, and the green pixel light-emitting layer 106 can emit light through the first anode layer 108.

Specifically, in one embodiment, the first cathode layer 109 is made of magnesium silver alloy.

Specifically, in one embodiment, a thickness of the first cathode layer 109 is between 500 Å and 1500 Å. More specifically, the thickness of the first cathode layer 109 is 500 Å, 600 Å, 700 Å, 850 Å, 1000 Å, 1150 Å, 1300 Å, or 1500 Å, wherein the specific thickness of the first cathode layer 109 is set by specific process requirements of the dual-sided display panel 10.

Specifically, in one embodiment, a thickness of the first anode layer 108 is between 50 Å and 150 Å. More specifically, the thickness of the first anode layer 108 is 50 Å, 60 Å, 70 Å, 85 Å, 100 Å, 115 Å, 130 Å, or 150 Å, wherein the specific thickness of the first anode layer 108 is set by specific process requirements of the dual-sided display panel 10.

Please refer to FIG. 3, which is a third schematic structural view of a dual-sided display panel 10 provided by an embodiment of the present application. The dual-sided display panel 10 shown in FIG. 3 differs from the dual-sided display panel 10 shown in FIG. 2 in that the second anode layer 110 includes a reflective anode layer 1101 and a transparent anode layer 1102 adjoining each other, each of the first portion 1051 and the third portion 1061 is disposed corresponding to the reflective anode layer 1101, and each of the second portion 1052 and the fourth portion 1062 is disposed corresponding to the transparent anode layer 1102.

Specifically, it should be noted that the reflective anode layer 1101 is made of a non-transparent material, and the transparent anode layer 1102 is made of a transparent material. Therefore, light emitted by the first portion 1051 and the third portion 1061 will only be delivered in a direction from the second organic light-emitting unit 10b to the first organic light-emitting unit 10a. Light emitted by the second portion 1052 and the fourth portion 1062 will only be delivered in a direction from the first organic light-emitting unit 10a to the second organic light-emitting unit 10b, so that a light intensity of the light emitted by the first portion 1051 and the third portion 1061 in the direction from the second organic light-emitting unit 10b to the first organic light-emitting unit 10a is substantially the same as a light intensity of light emitted by the blue pixel light-emitting layer 102, thereby improving display uniformity of the dual-sided display panel 10.

Specifically, in one embodiment, a length of the reflective anode layer 1101 is less than or equal to a length of the transparent anode layer 1102.

It should be noted that due to light-emitting efficiency and lifespan issues, when an opening of the blue pixel light-emitting layer 102 is twice that of the red pixel light-emitting layer 105, and the opening of the blue pixel light-emitting layer 102 is twice that of the green pixel light-emitting layer 106, the dual-sided display panel 10 gives best display effects.

Specifically, the openings refer to lengths of the pixel light-emitting layers. Therefore, the opening of the blue pixel light-emitting layer 102 is a length of the blue pixel light-emitting layer 102, the opening of the red pixel light-emitting layer 105 is a length of the first portion 1051, and the opening of the green pixel light-emitting layer 106 is a length of the third portion 1061.

Accordingly, when the length of the reflective anode layer 1101 is equal to the length of the transparent anode layer 1102, the opening of the red pixel light-emitting layer 105 is half the length of the red pixel light-emitting layer 105, and the opening of the green pixel light-emitting layer 106 is half the length of the green pixel light-emitting layer 106. In this manner, the opening of the blue pixel light-emitting layer 102 is twice the opening of the red pixel light-emitting layer 105, and the opening of the blue pixel light-emitting layer 102 is twice the opening of the green pixel light-emitting layer 106, thereby enabling the dual-sided display panel 10 to achieve the best display effects.

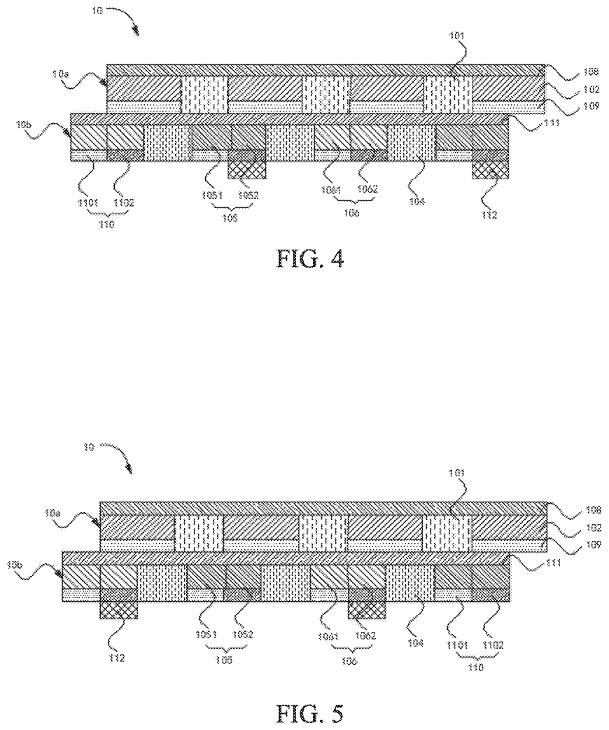

Please refer to FIGS. 4 and 5. FIG. 4 is a fourth schematic structural view of a dual-sided display panel 10 provided by an embodiment of the present application, and FIG. 5 is a fifth schematic structural view of a dual-sided display panel 10 provided by an embodiment of the present application. The dual-sided display panels 10 shown in FIGS. 4 and 5 differ from the dual-sided display panel 10 shown in FIG. 3 in that each of the dual-sided display panels 10 in FIGS. 4 and 5 further includes a conversion layer 112 disposed on a side of the transparent anode layer 102 away from the first organic light-emitting unit 10a and provided corresponding to the transparent anode layer 1102.

Specifically, it should be noted that since one side of the dual-sided display panel 10 needs to output three-color light, and the other side outputs monochromatic light, the conversion layer 112 is disposed to correspond to the transparent anode layer 1102, making the second portion 1052 and the fourth portion 1062 emit light of a same color.

Specifically, it should be noted that in FIG. 4, the conversion layer 113 is disposed corresponding to only the second portion 1052 and is configured to convert red light into green light. At this time, one side of the dual-sided display panel 10 can output the three-color light, and the other side can output green light.

Specifically, it should be noted that in FIG. 5, the conversion layer 112 is disposed corresponding to only the fourth portion 1062 and is configured to convert green light into red light. At this time, one side of the dual-sided display panel 10 can output the three-color light, and the other side can output red light.

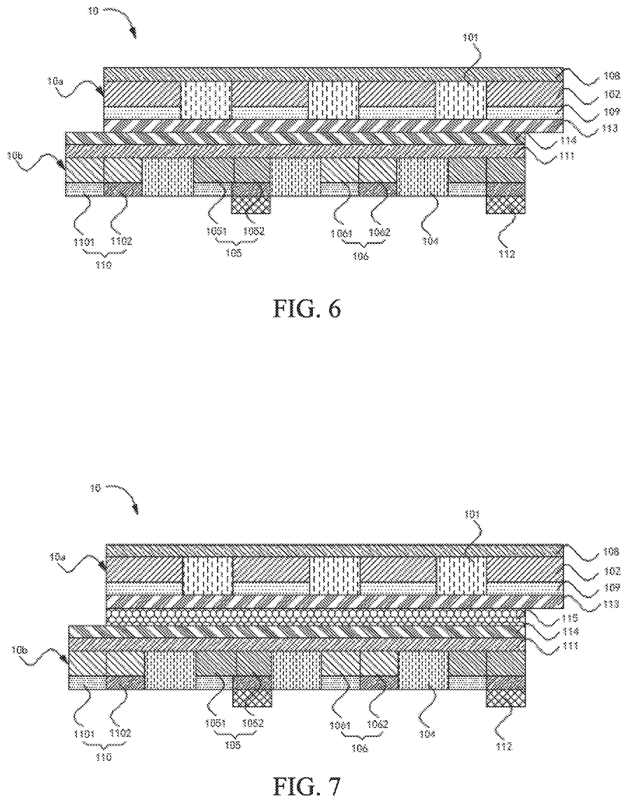

Please refer to FIG. 6, which is a sixth schematic structural view of a dual-sided display panel 10 provided by an embodiment of the present application. The dual-sided display panel 10 shown in FIG. 6 differs from the dual-sided display panel 10 shown in FIG. 5 in that the first organic light-emitting unit 10a further includes a first encapsulation layer 113 disposed on a side of the first cathode layer 109 away from the first anode layer 108, and the second organic light-emitting unit 10b further includes a second encapsulation layer 114 disposed on a side of the second cathode layer 111 away from the second anode layer 110.

Specifically, in one embodiment, the first encapsulation layer 113 and the second encapsulation layer 114 are made of nitrogen-containing flexible materials, oxygen-containing flexible materials, or silicon-containing flexible materials.

Specifically, in one embodiment, a thickness of each of the first encapsulation layer 113 and the second encapsulation layer 114 is between 0 μm and 15 μm. More specifically, the thickness of each of the first encapsulation layer 113 and the second encapsulation layer 114 is 0 μm, 1 μm, 2 μm, 4 μm, 6 μm, 9 μm, 12 μm, or 15 μm, wherein the specific thickness of the first encapsulation layer 113 and the second encapsulation layer 114 is set by specific process requirements of the dual-sided display panel 10.

Please refer to FIG. 7, which is a seventh schematic structural view of a dual-sided display panel 10 provided by an embodiment of the present application. The dual-sided display panel 10 shown in FIG. 7 differs from the dual-sided display panel 10 shown in FIG. 6 in that the dual-sided display panel 10 further includes an adhesion layer 115 disposed between the first encapsulation layer 113 and the second encapsulation layer 114.

In a dual-sided display panel provided by the present application, a first organic light-emitting unit includes a plurality of blue pixel light-emitting layers and a plurality of first pixel definition layers, and a second organic light-emitting unit includes a plurality of second pixel definition layers, a plurality of red pixel light-emitting layers, and a plurality of green pixel light-emitting layers. Each of the red pixel light-emitting layers includes a first portion and a second portion adjoining each other, and each of the green pixel light-emitting layers includes a third portion and a fourth portion adjoining each other. The first portion and the third portion are disposed to correspond to the first pixel definition layers, and the second portion and the fourth portion are disposed to correspond to the blue pixel light-emitting layers. Since the first pixel definition layers are transparent, only light emitted by the first portion and the third portion can be output from the first pixel definition layers, so that on the basis of not reducing lengths of the red pixel light-emitting layer and the green pixel light-emitting layer, an irradiation range of the light emitted by each of the red pixel light-emitting layer and the green pixel light-emitting layer is reduced, thereby increasing the resolution of the dual-sided display panel and satisfying the needs of consumers.

Correspondingly, an embodiment of the present application further provides a method of manufacturing a dual-sided display panel.

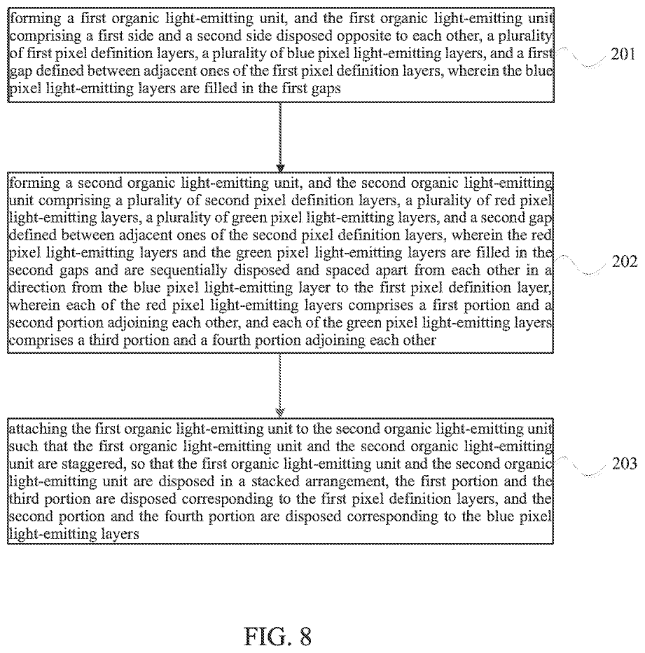

Please refer to FIG. 8, which is a flowchart of the method of manufacturing the dual-sided display panel provided by the embodiment of the present application. The method of manufacturing the dual-sided display panel provided by the embodiment of the present application includes:

Step 201: forming a first organic light-emitting unit, and the first organic light-emitting unit including a first surface and a second surface disposed opposite to each other, a plurality of first pixel definition layers, a plurality of blue pixel light-emitting layers, and a first gap defined between adjacent ones of the first pixel definition layers. The blue pixel light-emitting layers are filled in the first gaps.

Specifically, step 201 includes detailed steps as follows: providing a first anode layer, and forming the first pixel definition layers spaced apart from each other on the first anode layer, wherein the first gap is defined between adjacent ones of the first pixel definition layers; filling the blue pixel light-emitting layers in the first gaps; and forming a first cathode layer on the blue pixel light-emitting layers, wherein the first cathode layer is disposed on a side of the blue pixel light-emitting layers away from the first anode layer, and a side of the first cathode layer away from the first anode layer is flush with a side of each of the first pixel definition layers away from the anode layer.

Specifically, it should be noted that the first cathode layer is formed by an evaporation process.

Step 202: forming a second organic light-emitting unit, and the second organic light-emitting unit including a plurality of second pixel definition layers, a plurality of red pixel light-emitting layers, a plurality of green pixel light-emitting layers, and a second gap defined between adjacent ones of the second pixel definition layers, wherein the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers includes a first portion and a second portion adjoining each other, and each of the green pixel light-emitting layers includes a third portion and a fourth portion adjoining each other.

Specifically, step 202 includes detailed steps as follows: providing a plurality of second anode layers each including a reflective anode layer and a transparent anode layer adjoining each other, wherein the second gap is defined between adjacent ones of the second anode layers; filling the second pixel definition layers in the second gaps; forming the red pixel light-emitting layers and the green pixel light-emitting layers spaced apart from each other in sequence on the second anode layer, wherein a side of each of the red pixel light-emitting layers away from the second anode layer, a side of each of the green pixel light-emitting layers away from the second anode layer, and a side of each of the second pixel definition layers away from the second anode layer are all flush with each other; and forming a second cathode layer on the second pixel definition layers.

Specifically, it should be noted that the second cathode layer, the red pixel light-emitting layers, and the green pixel light-emitting layers are all formed by an evaporation process.

Step 203: attaching the first organic light-emitting unit to the second organic light-emitting unit such that the first organic light-emitting unit and the second organic light-emitting unit are staggered, so that the first organic light-emitting unit and the second organic light-emitting unit are disposed in a stacked arrangement, the first portion and the third portion are disposed corresponding to the first pixel definition layers, and the second portion and the fourth portion are disposed corresponding to the blue pixel light-emitting layers.

In the method of manufacturing the dual-sided display panel provided by the present application, the first organic light-emitting unit includes the blue pixel light-emitting layers and the first pixel definition layers, and the second organic light-emitting unit includes the second pixel definition layers, the red pixel light-emitting layers, and the green pixel light-emitting layers. Each of the red pixel light-emitting layers includes the first portion and the second portion adjoining each other, and each of the green pixel light-emitting layers includes the third portion and the fourth portion adjoining each other. The first portion and the third portion are disposed to correspond to the first pixel definition layers, and the second portion and the fourth portion are disposed to correspond to the blue pixel light-emitting layers. Since the first pixel definition layers are transparent, only light emitted by the first portion and the third portion can be output from the first pixel definition layers, so that on the basis of not reducing lengths of the red pixel light-emitting layer and the green pixel light-emitting layer, an irradiation range of the light emitted by each of the red pixel light-emitting layer and the green pixel light-emitting layer is reduced, thereby increasing the resolution of the dual-sided display panel and satisfying the needs of consumers.

In the above-mentioned embodiments, the description of each embodiment has its own emphasis. For parts that are not described in detail in an embodiment, reference may be made to related descriptions of other embodiments.

The dual-sided display panel and the method of manufacturing the same provided by the embodiments of the present application are described in detail above. Specific examples are used in this article to explain the principles and implementation of this application. The descriptions of the above embodiments are only used to help understand the technical solutions and core ideas of this application. Those of ordinary skill in the art should understand that: they can still modify the technical solutions described in the foregoing embodiments, or equivalently replace some of the technical features; and these modifications or replacements do not cause the essence of the corresponding technical solutions to deviate from the scope of the technical solutions of the embodiments of the present application.

What is claimed is:

1. A dual-sided display panel, comprising:
a first organic light-emitting unit and a second organic light-emitting unit disposed in a stacked arrangement;
wherein the first organic light-emitting unit comprises a plurality of first pixel definition layers and a plurality of blue pixel light-emitting layers, a first gap is defined between adjacent ones of the first pixel definition layers, and the blue pixel light-emitting layers are filled in the first gaps;
wherein the second organic light-emitting unit comprises a plurality of second pixel definition layers, a plurality of red pixel light-emitting layers, and a plurality of green pixel light-emitting layers, a second gap is defined between adjacent ones of the second pixel definition layers, and the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers comprises a first portion and a second portion adjoining each other, each of the green pixel light-emitting layers comprises a third portion and a fourth portion adjoining each other, the first portion and the third portion are disposed corresponding to the first pixel definition layers, and the second portion and the fourth portion are disposed corresponding to the blue pixel light-emitting layers.

2. The dual-sided display panel of claim 1, wherein the first organic light-emitting unit further comprises a first anode layer and a first cathode layer, the first anode layer is disposed on a side of the blue pixel light-emitting layer away from the second organic light-emitting unit, and the first cathode layer is disposed on a side of the blue pixel light-emitting layer adjacent to the second organic light-emitting unit.

3. The dual-sided display panel of claim 2, wherein the second organic light-emitting unit further comprises a second anode layer and a second cathode layer, the second anode layer is disposed on a side of the red pixel light-emitting layer away from the first organic light-emitting unit, the second cathode layer is disposed on a side of the red pixel light-emitting layer adjacent to the first organic light-emitting unit, and a side of the second cathode layer adjacent to the first organic light-emitting unit overlaps a side of the first cathode layer adjacent to the second organic light-emitting unit.

4. The dual-sided display panel of claim 3, wherein the second anode layer comprises a reflective anode layer and a transparent anode layer adjoining each other, each of the first portion and the third portion is disposed corresponding to the reflective anode layer, and each of the second portion and the fourth portion is disposed corresponding to the transparent anode layer.

5. The dual-sided display panel of claim 4, further comprising a conversion layer disposed on a side of the transparent anode layer away from the first organic light-emitting unit and provided corresponding to the transparent anode layer.

6. The dual-sided display panel of claim 3, wherein the first organic light-emitting unit further comprises a first encapsulation layer disposed on a side of the first cathode layer away from the first anode layer, and the second organic light-emitting unit further comprises a second encapsulation layer disposed on a side of the second cathode layer away from the second anode layer.

7. The dual-sided display panel of claim 6, further comprising an adhesion layer disposed between the first encapsulation layer and the second encapsulation layer.

8. The dual-sided display panel of claim 1, wherein each of the first pixel definition layer and the second pixel definition layer is made of colorless polyimide.

9. The dual-sided display panel of claim 4, wherein the reflective anode layer has a length less than or equal to a length of the transparent anode layer.

10. The dual-sided display panel of claim 1, wherein each of the blue pixel light-emitting layer, the red pixel light-emitting layer, and the green pixel light-emitting layer has a length between 20 microns (μm) and 25 μm.

11. A dual-sided display panel, comprising:
a first organic light-emitting unit and a second organic light-emitting unit disposed in a stacked arrangement;
wherein the first organic light-emitting unit comprises a plurality of first pixel definition layers and a plurality of blue pixel light-emitting layers, a first gap is defined between adjacent ones of the first pixel definition layers, and the blue pixel light-emitting layers are filled in the first gaps;
wherein the second organic light-emitting unit comprises a plurality of second pixel definition layers, a plurality of red pixel light-emitting layers, and a plurality of green pixel light-emitting layers, a second gap is defined between adjacent ones of the second pixel definition layers, and the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers comprises a first portion and a second portion adjoining each other, each of the green pixel light-emitting layers comprises a third portion and a fourth portion adjoining each other, the first portion and the third portion are disposed corresponding to the first pixel definition layers, and the second portion and the fourth portion are disposed corresponding to the blue pixel light-emitting layers; and
wherein each of the first pixel definition layer and the second pixel definition layer is made of colorless polyimide, and each of the blue pixel light-emitting layer, the red pixel light-emitting layer, and the green pixel light-emitting layer has a length between 20 microns (μm) and 25 μm.

12. The dual-sided display panel of claim 11, wherein the first organic light-emitting unit further comprises a first anode layer and a first cathode layer, the first anode layer is disposed on a side of the blue pixel light-emitting layer away from the second organic light-emitting unit, and the first cathode layer is disposed on a side of the blue pixel light-emitting layer adjacent to the second organic light-emitting unit.

13. The dual-sided display panel of claim 12, wherein the second organic light-emitting unit further comprises a second anode layer and a second cathode layer, the second anode layer is disposed on a side of the red pixel light-emitting layer away from the first organic light-emitting unit, the second cathode layer is disposed on a side of the red pixel light-emitting layer adjacent to the first organic light-emitting unit, and a side of the second cathode layer adjacent to the first organic light-emitting unit overlaps a side of the first cathode layer adjacent to the second organic light-emitting unit.

14. The dual-sided display panel of claim 13, wherein the second anode layer comprises a reflective anode layer and a transparent anode layer adjoining each other, each of the first portion and the third portion is disposed corresponding to the reflective anode layer, and each of the second portion and the fourth portion is disposed corresponding to the transparent anode layer.

15. The dual-sided display panel of claim 14, further comprising a conversion layer disposed on a side of the transparent anode layer away from the first organic light-emitting unit and provided corresponding to the transparent anode layer.

16. The dual-sided display panel of claim 13, wherein the first organic light-emitting unit further comprises a first encapsulation layer disposed on a side of the first cathode layer away from the first anode layer, and the second organic light-emitting unit further comprises a second encapsulation layer disposed on a side of the second cathode layer away from the second anode layer.

17. The dual-sided display panel of claim 16, further comprising an adhesion layer disposed between the first encapsulation layer and the second encapsulation layer.

18. The dual-sided display panel of claim 14, wherein the reflective anode layer has a length less than or equal to a length of the transparent anode layer.

19. The dual-sided display panel of claim 11, wherein a thickness of the blue pixel light-emitting layer is between 250 angstroms and 1000 angstroms, a thickness of the red pixel light-emitting layer is between 500 angstroms and 2000 angstroms, and a thickness of the green pixel light-emitting layer is between 400 angstroms and 1000 angstroms.

20. A method of manufacturing a dual-sided display panel, comprising:
forming a first organic light-emitting unit, and the first organic light-emitting unit comprising a first surface and a second surface disposed opposite to each other, a plurality of first pixel definition layers, a plurality of blue pixel light-emitting layers, and a first gap defined between adjacent ones of the first pixel definition layers, wherein the blue pixel light-emitting layers are filled in the first gaps;
forming a second organic light-emitting unit, and the second organic light-emitting unit comprising a plurality of second pixel definition layers, a plurality of red pixel light-emitting layers, a plurality of green pixel light-emitting layers, and a second gap defined between adjacent ones of the second pixel definition layers, wherein the red pixel light-emitting layers and the green pixel light-emitting layers are filled in the second gaps and are sequentially disposed and spaced apart from each other in a direction from the blue pixel light-emitting layer to the first pixel definition layer, wherein each of the red pixel light-emitting layers comprises a first portion and a second portion adjoining each other, and each of the green pixel light-emitting layers comprises a third portion and a fourth portion adjoining each other; and
attaching the first organic light-emitting unit to the second organic light-emitting unit such that the first organic light-emitting unit and the second organic light-emitting unit are staggered, so that the first organic light-emitting unit and the second organic light-emitting unit are disposed in a stacked arrangement, the first portion and the third portion are disposed corresponding to the first pixel definition layers, and the second portion and the fourth portion are disposed corresponding to the blue pixel light-emitting layers.
